(19) United States
(12) Patent Application Publication
(10) Pub. No.: US 2006/0172473 A1
(43) Pub. Date: Aug. 3, 2006

(54) METHOD OF FORMING A TWO-LAYER GATE DIELECTRIC

(76) Inventors: Po-Lun Cheng, Kao-Hsiung Hsien (TW); Li-Wei Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/906,104

(22) Filed: Feb. 3, 2005

(51) Int. Cl. H01L 21/84; H01L 21/31

(52) U.S. Cl. 438/151; 438/786

(57) ABSTRACT

A substrate is provided, and a silicon dioxide thin film is formed thereon. Subsequently, an amorphous silicon thin film is formed over the silicon dioxide thin film, and a low temperature plasma nitridation process is preformed to form a nitrogen-containing amorphous silicon thin film. Following that, an oxygen annealing process is carried out to form a nitrogen-rich silicon oxynitride layer.

### BACKGROUND OF INVENTION

1. Field of the Invention

The present invention relates to a method of forming a two-layer gate dielectric, and more particularly, to a method of forming a two-layer gate dielectric composed of a silicon dioxide thin film and a nitrogen-rich silicon oxynitride layer.

2. Description of the Prior Art

As the rapid development of semiconductor technology progresses, the critical dimension of semiconductor processes is reduced unceasingly. To date, the gate width has been improved to 70 nm or even less, and the thickness of the gate oxide layer is also reduced to about 1.5 nm. With the reduction of the thickness of the gate oxide layer, however, the gate leakage current is accordingly generated. Recently, silicon oxynitride, which has a higher dielectric constant (k value), has been developed to replace the silicon dioxide layer as the gate oxide layer. The actual thickness of the silicon nitride layer is thicker than the actual thickness of the silicon dioxide layer, while the equivalent oxide thickness (EOT) of the silicon nitride layer and the EOT of the silicon dioxide layer are identical. Consequently, the gate leakage current is reduced.

Please refer to FIG. 1 through FIG. 4. FIG. 1 through FIG. 4 are schematic diagrams illustrating a conventional method of forming a gate dielectric. As shown in FIG. 1, a substrate 10 is provided, and a silicon dioxide layer 12 is formed thereon. As shown in FIG. 2 and FIG. 3, a high temperature plasma nitridation process is performed by introducing nitrogen at a high temperature and utilizing plasma to bombard the silicon dioxide 12 so as to form a oxygen-rich silicon oxynitride layer 14. As shown in FIG. 4, then a polysilicon layer 16 is formed on the oxygen-rich silicon oxynitride layer 14.

The conventional method as previously described, however, has the following disadvantages. First, the high temperature plasma nitridation process can damage the surface of the substrate 10, and drive diffusion of nitrogen atoms to the interface of the substrate 10 and the silicon dioxide layer 12. This would degrade the performance and reliability. Second, although the interface between the oxygen-rich silicon oxynitride layer 14 and the substrate 10 is slightly better than the interface between a silicon nitride layer and the substrate 10, the interface between the oxygen-rich silicon oxynitride layer 14 and the substrate 10 is still far interior to the interface between a silicon dioxide layer and the substrate 10. In addition, the k value of the oxygen-rich silicon oxynitride layer 14 is not very high. Namely, the actual thickness of the oxygen-rich silicon oxynitride layer 14 is not thick enough to inhibit the gate leakage current.

### SUMMARY OF INVENTION

It is therefore a primary object of the claimed invention to provide a method of forming a two-layer gate dielectric to overcome the aforementioned problems.

According to a preferred embodiment of the claimed invention, a method of forming a two-layer gate dielectric is disclosed. First, a substrate is provided, and a silicon dioxide thin film is formed on the substrate. Then, an amorphous silicon thin film is formed on the silicon dioxide thin film. Subsequently, a low temperature plasma nitridation process is performed to convert the amorphous silicon thin film into a nitrogen-containing amorphous silicon thin film. Following that, an oxygen annealing process is performed to convert the nitrogen-containing amorphous silicon thin film into a nitrogen-rich silicon oxynitride layer. The silicon dioxide thin film and the nitrogen-rich silicon oxynitride layer form the two-layer gate dielectric.

As above described, a silicon dioxide thin film is primarily formed on the substrate to ensure an improved interface between the silicon dioxide thin film and the substrate. Following that, an amorphous silicon thin film is formed to prevent diffusion of nitrogen atoms into the interface between the silicon dioxide thin film and the substrate during the subsequent process. Subsequently, a low temperature plasma nitridation process and an oxygen annealing process are consecutively carried out to form a nitrogen-rich silicon oxynitride layer. The nitrogen-rich silicon oxynitride layer has a higher k value compared to the oxygen-rich silicon oxynitride layer, and thus can obtain the same EOT as the oxygen-rich silicon oxynitride layer with a thinner actual thickness. Therefore, the gate leakage current is inhibited, and the gate is able to have a higher threshold voltage.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 through FIG. 4 are schematic diagrams illustrating a conventional method of forming a gate dielectric.

FIG. 5 through FIG. 10 are schematic diagrams illustrating a method of forming a two-layer gate dielectric according to a preferred embodiment of the present invention.

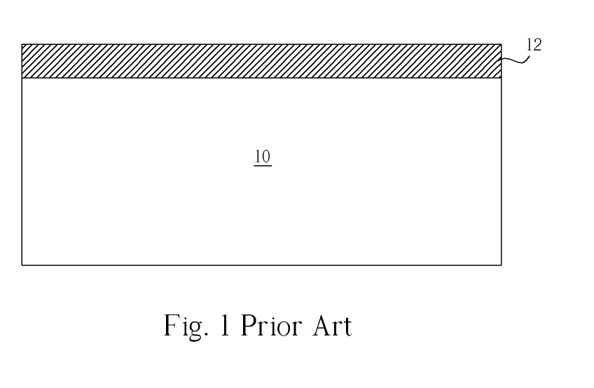

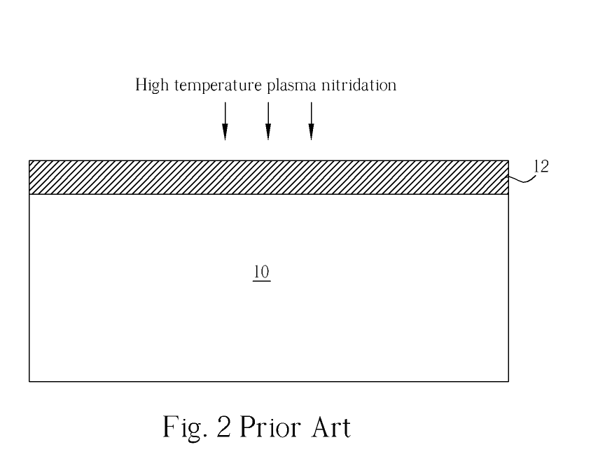

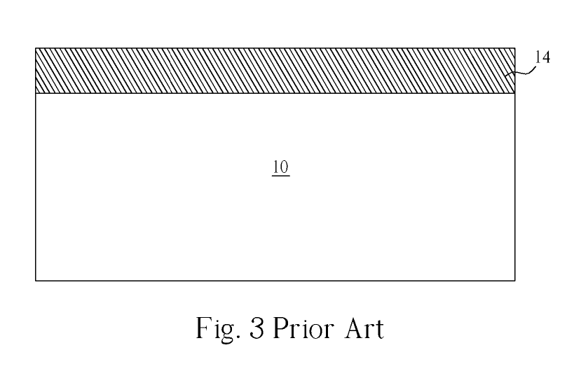

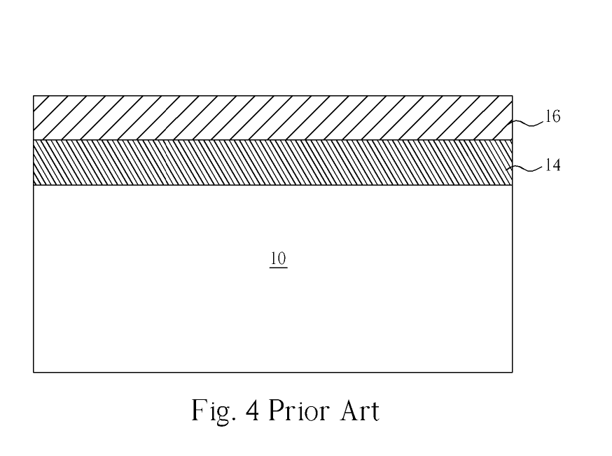

### DETAILED DESCRIPTION

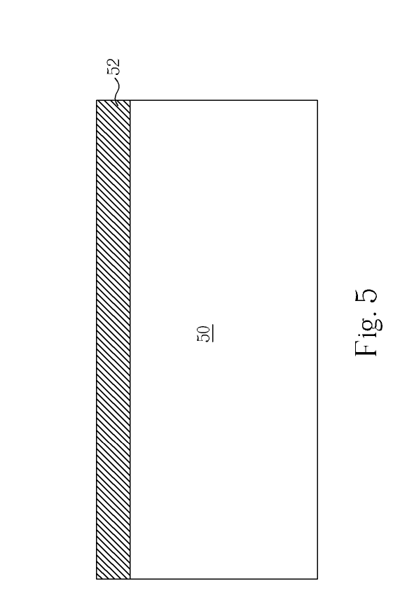

Please refer to FIG. 5 through FIG. 10. FIG. 5 through FIG. 10 are schematic diagrams illustrating a method of forming a two-layer gate dielectric according to a preferred embodiment of the present invention. As shown in FIG. 5, a substrate 50, such as a silicon substrate, is provided, and a silicon dioxide thin film 52 is formed on the substrate 50. In this embodiment, the silicon dioxide thin film 52 has a thickness of between 5 to 80 angstroms, and is formed using a chemical vapor deposition process at a temperature under 400° C. to ensure a good interface between the substrate 50 and the silicon dioxide thin film 52. However, the formation of the silicon dioxide thin film 52 is not limited by this, and can be implemented by other processes, e.g. a thermal oxidation process.

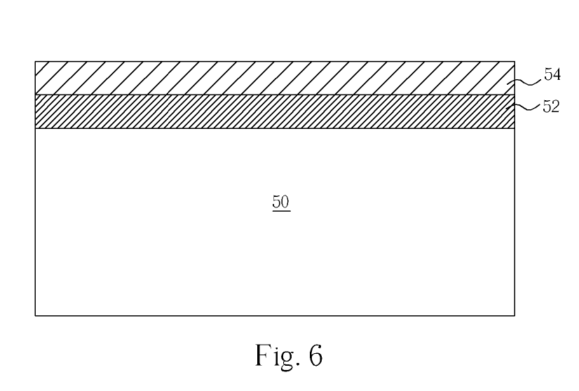

As shown in FIG. 6, an amorphous silicon thin film 54 is formed on the silicon dioxide thin film 52. In this embodiment, the amorphous silicon thin film 54 has a thickness of less than 10 angstroms. The amorphous silicon thin film 54 is formed for two main reasons. First, the amorphous silicon thin film 54 can prevent damage of the interface between the silicon dioxide thin film 52 and the substrate 50 in a plasma nitridation process to be performed. Second, the amorphous silicon thin film 54 is able to keep the nitrogen atoms in the upper portion of a nitrogen-containing amorphous silicon thin film (not shown) to be formed.

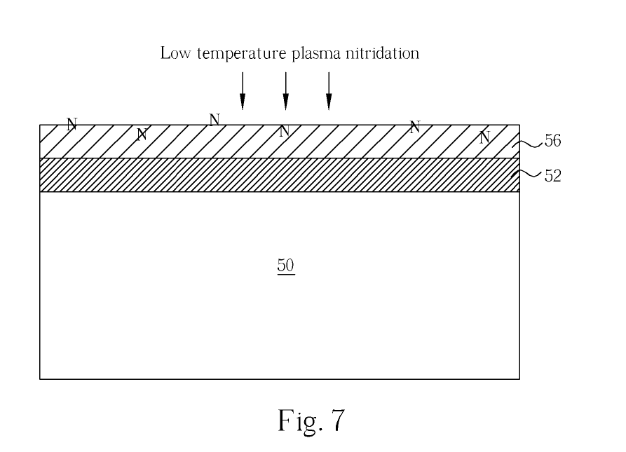

As shown in FIG. 7, a nitridation process, e.g. a low temperature plasma nitridation process, is carried out by introducing nitrogen and utilizing plasma to bombard the amorphous silicon thin film 54. Consequently, the amorphous silicon thin film 54 is converted into a nitrogen-containing amorphous silicon thin film 56. In this embodiment, the low temperature plasma nitridation process is performed at a temperature under 400° C. to prevent the interface between the silicon dioxide thin film 52 and the substrate 50 from being damaged, and to keep the nitrogen atoms in the upper portion of the nitrogen-containing amorphous silicon thin film 56.

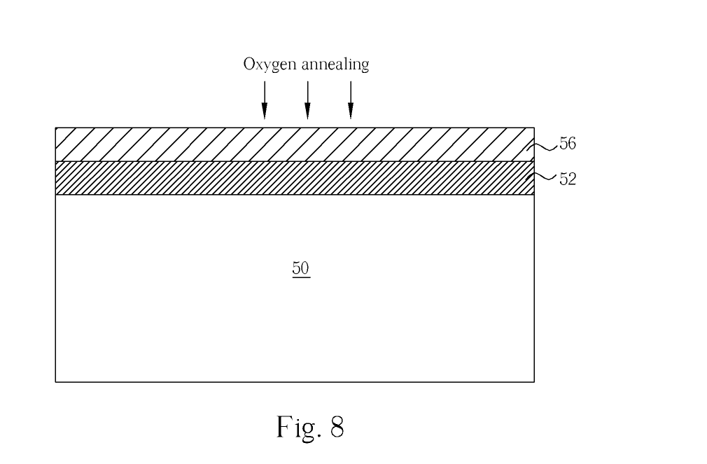

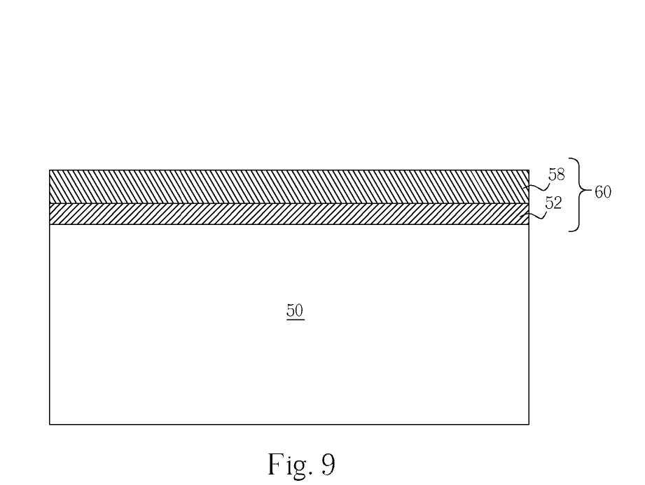

As shown in FIG. 8 and FIG. 9, an oxidation process, e.g. an oxygen annealing process, is performed to convert the nitrogen-containing amorphous thin film 56 into a nitrogen-rich silicon oxynitride layer 58, where the silicon dioxide thin film 52 and the nitrogen-rich silicon oxynitride layer 58 form the two-layer gate dielectric 60 of the present invention. Since nitrogen-rich silicon oxynitride has a higher k value than silicon dioxide, the actual thickness of the nitrogen-rich silicon oxynitride layer 58 is much thicker than the actual thickness of a silicon dioxide layer. Consequently, the gate leakage current is reduced, and the gate can be driven with a higher threshold voltage. It is to be noted that if the interface between the silicon dioxide thin film 52 and the substrate is damaged during the low temperature plasma nitridation process, the oxygen annealing process is able to recover the interface between the silicon dioxide thin film 52 and the substrate.

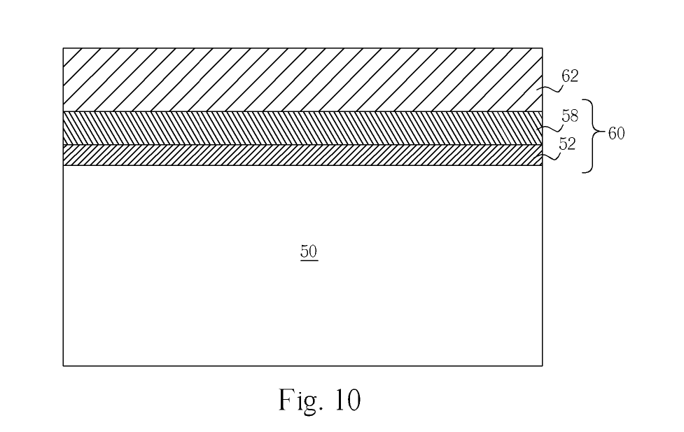

As shown in FIG. 10, a gate 62, such as a polysilicon gate, is formed on the nitrogen-rich silicon oxynitride layer 58.

According to the method of the present invention, a silicon dioxide thin film is primarily formed on the substrate to ensure an improved interface between the silicon dioxide thin film and the substrate. Following that, an amorphous silicon thin film is formed to prevent diffusions of nitrogen atoms into the interface between the silicon dioxide thin film and the substrate during the subsequent process. Subsequently, a low temperature plasma nitridation process and an oxygen annealing process are consecutively carried out to form a nitrogen-rich silicon oxynitride layer. The nitrogen-rich silicon oxynitride layer has a higher k value compared to the oxygen-rich silicon oxynitride layer, and thus can obtain the same EOT as the oxygen-rich silicon oxynitride layer with a thinner actual thickness. Therefore, the gate leakage current is inhibited, and the gate is able to have a higher threshold voltage.

In comparison with the prior art, the method of the present invention benefits from a good interface between the silicon dioxide thin film and the substrate, low diffusion of nitrogen atoms, and a high k value of the two-layer gate dielectric.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a two-layer gate dielectric, comprising: providing a substrate;
forming a silicon dioxide thin film on the substrate;
forming an amorphous silicon thin film on the silicon dioxide thin film;
performing a low temperature plasma nitridation process to convert the amorphous silicon thin film into a nitrogen-containing amorphous silicon thin film;
performing an oxygen annealing process to convert the nitrogen-containing amorphous silicon thin film into a nitrogen-rich silicon oxynitride layer;
wherein the silicon dioxide thin film and the nitrogen-rich silicon oxynitride layer form the two-layer gate dielectric.

2. The method of claim 1, further comprising a step of forming a gate over the nitrogen-rich silicon oxynitride layer after the nitrogen-rich silicon oxynitride layer is formed.

3. The method of claim 1, wherein the silicon dioxide thin film is formed using a chemical vapor deposition process.

4. The method of claim 1, wherein the silicon dioxide thin film is formed using an oxidation process.

5. The method of claim 1, wherein the silicon dioxide thin film has a thickness of between 5 to 80 angstroms.

6. The method of claim 1, wherein the amorphous silicon thin film is formed using a chemical vapor deposition process.

7. The method of claim 6, wherein the chemical vapor deposition process is performed at a temperature under 400° C.

8. The method of claim 1, wherein the amorphous silicon thin film has a thickness of less than 10 angstroms.

9. The method of claim 1, wherein the low temperature plasma nitridation process is performed at a temperature under 400° C.

10. A method of forming a two-layer gate dielectric, comprising:
providing a substrate;
forming a silicon dioxide thin film on the substrate;
forming an amorphous silicon thin film on the silicon dioxide thin film;
performing an oxidation process to covert the amorphous silicon thin film into a nitrogen-containing amorphous silicon thin film; and
performing a nitridation process to convert the nitrogen-containing amorphous silicon thin film into a nitrogen-rich silicon oxynitride layer;
wherein the silicon dioxide thin film and the nitrogen-rich silicon oxynitride layer form the two-layer gate dielectric.

11. The method of claim 10, further comprising a step of forming a gate over the nitrogen-rich silicon oxynitride layer after the nitrogen-rich silicon oxynitride layer is formed.

12. The method of claim 10, wherein the silicon dioxide thin film is formed using a chemical vapor deposition process.

13. The method of claim 10, wherein the silicon dioxide thin film is formed using an oxidation process.

14. The method of claim 10, wherein the silicon dioxide thin film has a thickness of between 5 to 80 angstroms.

15. The method of claim 10, wherein the amorphous silicon thin film is formed using a chemical vapor deposition process.

16. The method of claim 15, wherein the chemical vapor deposition process is performed at a temperature under 400° C.

17. The method of claim 10, wherein the amorphous silicon thin film has a thickness of less than 10 angstroms.

18. The method of claim 10, wherein the nitridation process is a low temperature plasma nitridation process performed at a temperature under 400° C.

19. The method of claim 10, wherein the oxidation process is an oxygen annealing process.
